(19) United States
(12) Patent Application Publication
(10) Pub. No.: US 2021/0296553 A1
(43) Pub. Date: Sep. 23, 2021

(54) HIGH-POWER THERMOELECTRIC CONVERSION MODULE AND THERMOELECTRIC CONVERSION SYSTEM

(71) Applicant: Shandong University, Shandong (CN)

(72) Inventors: Hongchao WANG, Shandong (CN); Xue WANG, Shandong (CN); Wenbin SU, Shandong (CN); Chunlei WANG, Shandong (CN)

(73) Assignee: Shandong University, Shandong (CN)

(21) Appl. No.: 16/629,036

(22) PCT Filed: Apr. 12, 2019
(86) PCT No.: PCT/CN2019/082481

§ 371 Date: Jan. 7, 2020

(30) Foreign Application Priority Data
Mar. 20, 2019 (CN) 201910213356.6

(51) Int. Cl. H01L 35/32; H01L 35/08; H01L 35/10

(52) U.S. Cl. CPC H01L 35/32; H01L 35/10; H01L 35/08

(57) ABSTRACT

The present invention relates to a high-power thermoelectric conversion module and thermoelectric conversion system. The thermoelectric conversion module includes: a first substrate made of ceramic; a second substrate made of ceramic and disposed opposite to the first substrate; a plurality of third electrodes and thermoelectric conversion elements arranged crosswise in a matrix between the first substrate and the second substrate; a first electrode disposed between the first substrate and the thermoelectric conversion elements; and a second electrode disposed between the second substrate and the thermoelectric conversion elements. The first electrode is connected to one ends of the thermoelectric conversion elements and the third electrodes whose tops are flush with the one ends of the thermoelectric conversion elements, respectively. The second electrode is connected to the other ends of the thermoelectric conversion elements and the third electrodes whose bottoms are flush with the other ends of the thermoelectric conversion elements, respectively.

### BACKGROUND

### Technical Field

The present disclosure belongs to the field of semiconductor thermoelectric power generation technology, and specifically relates to a single-leg electrical-thermal-parallel high-power multilayer composite structured thermoelectric conversion module and a thermoelectric conversion system thereof.

### Description of Related Art

In the past few centuries, the massive use of fossil fuels such as coal, oil and natural gas has contributed to the rapid development of industrial society, but has also caused serious energy crises and environmental degradation. The thermoelectric device is a new energy conversion device that can directly convert thermal energy and electric energy to each other, has the advantages of cleanness, environmental friendliness, no mechanical moving parts, low noise, fast response, light weight, small size, easy maintenance, safety, reliability, etc., can improve energy utilization and alleviate resource depletion and environmental degradation, and therefore has very high potential application value.

The inventors have found in the research that the conventional thermoelectric device is usually constituted by connecting n-type and p-type thermoelectric legs in an electrical-series connection and thermal-parallel connection manner through a metal electrode. The n-type and p-type thermoelectric legs are usually cuboid or cylindrical. In an operating state, the heat flux in the thermoelectric material is uniform, a large temperature difference is easy to achieve, and a high output voltage is obtained accordingly. However, the operating current of the conventional thermoelectric device is low, so the output power is always low and cannot meet the industrial requirements.

Based on the above, the existing thermoelectric devices lack effective technical solutions for the problem of low output power.

### SUMMARY

In order to overcome the above deficiencies of the prior art, the present disclosure provides a high-power thermoelectric conversion module and a thermoelectric conversion system. The thermoelectric conversion module proposed by the present disclosure has an electro-thermal conduction mode of electrical-parallel connection and thermal-parallel connection, can simultaneously obtain high output voltage and operating current, and achieves very high output power under certain temperature difference.

The technical solution adopted by the present disclosure is:

A thermoelectric conversion module, including:

a first substrate made of ceramic;

a second substrate made of ceramic and disposed opposite to the first substrate;

a plurality of third electrodes and thermoelectric conversion elements arranged crosswise in a matrix between the first substrate and the second substrate;

a first electrode disposed between the first substrate and the thermoelectric conversion elements; and

a second electrode disposed between the second substrate and the thermoelectric conversion elements,

wherein the first electrode is connected to one sides of the thermoelectric conversion elements and the third electrodes whose tops are flush with one ends of the thermoelectric conversion elements, respectively; and

wherein the second electrode is connected to the other sides of the thermoelectric conversion elements and the third electrodes whose bottoms are flush with the other ends of the thermoelectric conversion elements, respectively.

Through the above technical solution, when the upper and lower ends of the thermoelectric conversion module have certain temperature difference, the thermoelectric conversion module has an electro-thermal conduction mode of electrical-parallel connection and thermal-parallel connection, can simultaneously obtain high output voltage and operating current, and achieves very high output power.

Further, the third electrodes have the same length as the thermoelectric conversion elements, and the thermoelectric conversion elements are higher and wider than the third electrodes; and the thermoelectric conversion elements are made of only one kind of n-type or p-type thermoelectric materials.

Further, two adjacent third electrodes are misaligned in the height direction, the top of one third electrode is flush with one ends of the thermoelectric conversion elements and connected to the first electrode, and a gap is reserved between the second electrode and the bottom of the one third electrode; a gap is reserved between the first electrode and the top of the other third electrode, and the bottom of the other third electrode is flush with the other ends of the thermoelectric conversion elements and connected to the second electrode.

Through the above technical solution, the third electrodes connected to the second electrode are used for transferring heat from the second electrode to one side of the thermoelectric material element, and the third electrodes connected to the first electrode are used for transferring heat from the other side of the thermoelectric material element to the first electrode. Furthermore, the two third electrodes on two sides of the thermoelectric material respectively serve as a hot end and a cold end of the thermoelectric material, thereby providing a horizontal temperature difference for the thermoelectric material. In addition, the third electrodes are also used to connect a plurality of thermoelectric material elements in the individual thermoelectric elements, so that the thermoelectric material elements are electrically connected in parallel between the first and second substrates, and the electrical effect of third electrodes is similar to that of wires.

Further, the first electrode, the second electrode, and the third electrodes are made of the same material.

A thermoelectric conversion module, including:

a first substrate made of ceramic;

a second substrate made of ceramic and disposed opposite to the first substrate;

a plurality of first inner electrodes and n-type thermoelectric conversion elements arranged crosswise in a matrix between the first substrate and the second substrate;

a plurality of second inner electrodes and p-type thermoelectric conversion elements arranged crosswise in a matrix between the first substrate and the second substrate;

a first outer electrode disposed between the first substrate and the n-type thermoelectric conversion elements, the p-type thermoelectric conversion elements;

a second outer electrode disposed between the second substrate and the n-type thermoelectric conversion element; and

a third outer electrode disposed between the second substrate and the p-type thermoelectric conversion element.

Through the above technical solution, the π-type thermoelectric conversion module, which is formed by connecting n-type thermoelectric conversion elements and p-type thermoelectric conversion elements in series and employs an electro-thermal conduction mode of series-parallel electrical transmission and parallel thermal transmission, has high output voltage and high operating current, thereby greatly improving the output power.

Further, two adjacent first inner electrodes are misaligned in the height direction, the top of one first inner electrode is flush with one ends of the n-type thermoelectric conversion elements and connected to the first outer electrode, and a gap is reserved between the second outer electrode and the bottom of the one first inner electrode; a gap is reserved between the first outer electrode and the top of the other first inner electrode, and the bottom of the other first inner electrode is flush with the other ends of the n-type thermoelectric conversion elements and connected to the second outer electrode.

Further, two adjacent second inner electrodes are misaligned in the height direction, the top of one second inner electrode is flush with one ends of the p-type thermoelectric conversion elements and connected to the first outer electrode, and a gap is reserved between the third outer electrode and the bottom of one second inner electrode; a gap is reserved between the first outer electrode and the top of the other second inner electrode, and the bottom of the other second inner electrode is flush with the other ends of the p-type thermoelectric conversion elements and connected to the third outer electrode.

Through the above technical solution, the second outer electrode is connected to the second ceramic substrate (hot end) to provide heat for the thermoelectric material and the inner electrodes connected thereto; the first outer electrode is connected to the first ceramic substrate (cold end) to absorb heat from the thermoelectric material and the inner electrodes connected thereto, and the outer electrode plays a role in transferring heat; the metal inner electrode connected to the first outer electrode, the thermoelectric material, and the metal inner electrode connected to the second outer electrode form a branch, four branches are connected in parallel to the first and second outer electrodes to form an electrical parallel connection, and the outer electrodes play a role in connecting a circuit. The gaps in the middle are to avoid the disappearance of temperature difference in the horizontal direction. With the small gaps, the inner electrodes are as high as possible to the thermoelectric material, and then a larger horizontal temperature difference is provided to the thermoelectric material.

Further, the first outer electrode is connected to one ends of the n-type thermoelectric conversion elements, the first inner electrodes whose tops are flush with the one ends of the n-type thermoelectric conversion elements, one ends of the p-type thermoelectric conversion elements, and the second inner electrodes whose tops are flush with the one ends of the p-type thermoelectric conversion elements, respectively;

the second outer electrode is connected to the other ends of the n-type thermoelectric conversion elements, and the first inner electrodes whose bottoms are flush with the other ends of the n-type thermoelectric conversion elements, respectively;

the third outer electrode is connected to the other ends of the p-type thermoelectric conversion elements, and the second inner electrodes whose bottoms are flush with the other ends of the p-type thermoelectric conversion elements, respectively.

Further, the first outer electrode, the second outer electrode and the third outer electrode are made of the same material; the first inner electrodes and the second inner electrodes are made of the same material.

A thermoelectric conversion system, including:

the thermoelectric conversion module as described above; and

a heat source disposed on the second substrate.

Through the above technical solutions, the beneficial effects of the present disclosure are as follows:

(1) By employing an electro-thermal conduction mode of electrical-parallel connection and thermal-parallel connection, the present disclosure has high output voltage and high operating current, thereby greatly improving the output power; under the same condition, the thermoelectric conversion module made of only an n-type or p-type thermoelectric material can achieve high output power without considering the performance matching of n-type and p-type thermoelectric materials; the n-type and p-type thermoelectric conversion modules are connected in series to form a π-type thermoelectric conversion module, the output power of which can reach five times the output power of the conventional thermoelectric module;

(2) The transmission of heat flux and current can be optimized by increasing the thickness of the metal electrodes, the transmission of heat flux and current between different materials can also be balanced by optimizing the geometric structure of the thermoelectric material, and the output power of the thermoelectric conversion module is improved accordingly.

### BRIEF DESCRIPTION OF THE DRAWINGS

The accompanying drawings constituting a part of the present disclosure are used for providing a further understanding of the present disclosure, and the schematic embodiments of the present disclosure and the descriptions thereof are used for interpreting the present disclosure, rather than constituting improper limitations to the present disclosure.

FIG. 1 is a perspective view of a thermoelectric conversion module according to Embodiment 1;

FIG. 2 is a front view of the thermoelectric conversion module according to Embodiment 1;

FIG. 3 is a top view of the thermoelectric conversion module according to Embodiment 1;

FIG. 4 is a side view of the thermoelectric conversion module according to Embodiment 1;

FIG. 5 is a perspective view of a thermoelectric conversion module according to Embodiment 2;

FIG. 6 is a front view of the thermoelectric conversion module according to Embodiment 2;

FIG. 7 is a top view of the thermoelectric conversion module according to Embodiment 2;

FIG. 8 is a side view of the thermoelectric conversion module according to Embodiment 2;

FIG. 9 is a schematic view of performance comparison between the thermoelectric conversion module according to Embodiment 2 and the conventional thermoelectric conversion module of the same material volume;

FIG. 10 is a schematic view of performance of thermoelectric conversion modules of different metal electrode thicknesses according to Embodiment 2.

### DESCRIPTION OF THE EMBODIMENTS

The present disclosure will be further illustrated below in conjunction with the accompanying drawings and embodiments.

It should be pointed out that the following detailed descriptions are all exemplary and aim to further illustrate the present disclosure. Unless otherwise specified, all technological and scientific terms used in the present disclosure have the same meanings generally understood by those of ordinary skill in the art of the present disclosure.

It should be noted that the terms used herein are merely for describing specific embodiments, but are not intended to limit exemplary embodiments according to the present application. As used herein, unless otherwise explicitly pointed out by the context, the singular form is also intended to include the plural form. In addition, it should also be understood that when the terms “include” and/or “comprise” are used in the specification, they indicate features, steps, operations, devices, components and/or their combination.

### Embodiment 1

For the problem of low output power of the existing thermoelectric module, the present embodiment provides a thermoelectric conversion module capable of achieving high output power under certain temperature difference.

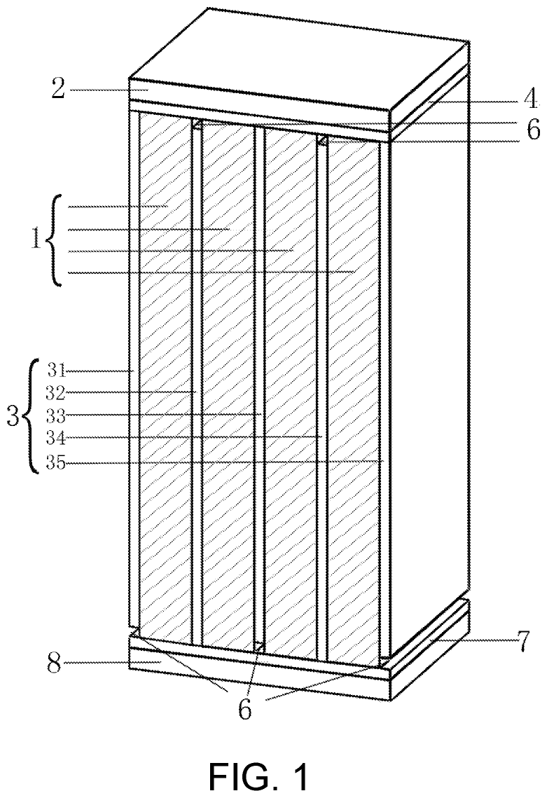

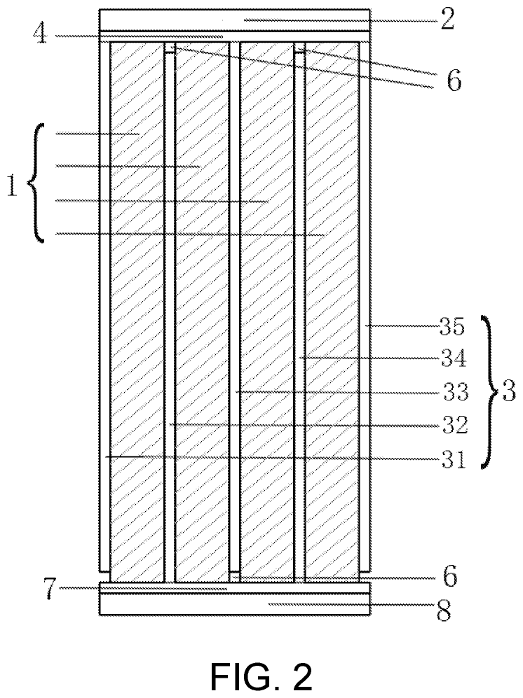

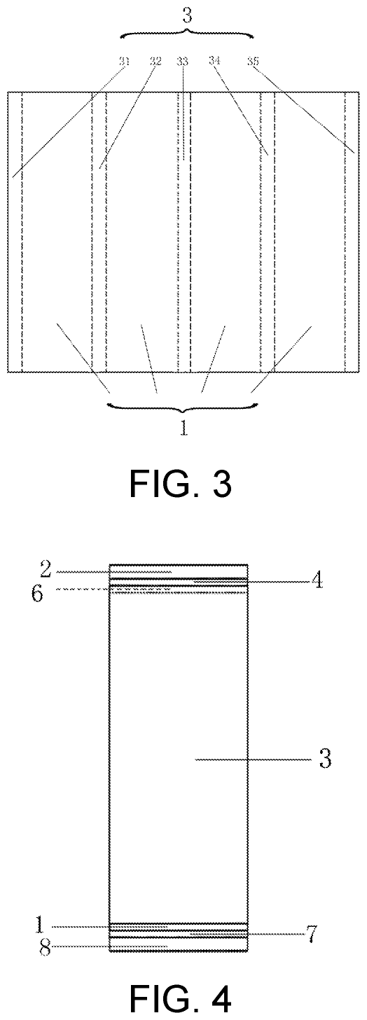

FIG. 1 is a perspective view of a thermoelectric conversion module according to Embodiment 1. FIG. 2 is a front view of FIG. 1, FIG. 3 is a top view of FIG. 1, and FIG. 4 is a side view of FIG. 1. The thermoelectric conversion module of the present embodiment includes a first substrate 2 made of ceramic, a first electrode 4, a plurality of thermoelectric conversion elements 1, a second electrode 7, a second substrate 8 made of ceramic, and a plurality of third electrodes 3.

Specifically, the first substrate 2 and the second substrate 8 are disposed opposite to each other, the plurality of third electrodes 3 and thermoelectric conversion elements 1 are arranged crosswise in a matrix along the width and disposed between the first substrate 2 and the second substrate 8, a thermoelectric conversion element 1 is disposed between two adjacent third electrodes 3, one end of the thermoelectric conversion elements 1 is flush with the top of one third electrode 3 and the other endo the thermoelectric conversion elements 1 is flush with the bottom of the other third electrode 3, and the first electrode 4 is disposed on the inner side surface of the first substrate 2, and electrically connected in parallel to one ends of the plurality of thermoelectric conversion elements 1 and the third electrodes 3 whose tops are flush with the one ends of the plurality of thermoelectric conversion elements 1, respectively; the second electrode 7 is disposed on the inner side surface of the second substrate 8, and electrically connected in parallel to the other ends of the plurality of thermoelectric conversion elements 1 and the third electrodes 3 whose bottoms are flush with the other ends of the plurality of thermoelectric conversion elements 1, respectively.

In the thermoelectric conversion module of the present embodiment, when the upper and lower ends of the module have certain temperature difference, if the upper end is a hot end, the heat flux in the thermoelectric conversion module flows in order of the first substrate 2, the first electrode 4, the third electrode 3 connected to the first electrode 4, the thermoelectric conversion element 1, the third electrode 3 connected to the second electrode 7, the second electrode 7, and the second substrate 8; if the lower end is a hot end, the heat flux in the thermoelectric conversion module flows in order of the second substrate 8, the second electrode 7, the third electrode 3 connected to the second electrode 7, the thermoelectric conversion element 1, the third electrode 3 connected to the first electrode 4, the first electrode 4, and the first substrate 2.

In the present embodiment, the thermoelectric conversion elements 1 are formed, for example, in a plate shape, and the thermoelectric conversion elements 1 are made of an n-type or p-type thermoelectric material. Due to the Seebeck effect, carrier electrons in the n-type thermoelectric material and carrier holes in the p-type thermoelectric material move from the hot end to the cold end, and a potential difference is then generated at the two ends of the thermoelectric material. After a load resistor is applied, current is generated in the circuit composed of the thermoelectric module and the load resistor, the current in the p-type thermoelectric material is conducted along the direction of the heat flux, the current in the n-type thermoelectric material is conducted opposite to direction of the heat flux, and the current and the heat flux in the thermoelectric conversion module are conducted in parallel.

In the present embodiment, the first substrate 2 is formed, for example, in a plate shape, is electrically insulated, has good thermal conductivity, and covers the one ends of the plurality of thermoelectric conversion elements 1.

The second substrate 8 is formed, for example, in a plate shape, is electrically insulated, has good thermal conductivity, and covers the other ends of the plurality of thermoelectric conversion elements 1.

In the present embodiment, the material of the first electrode 4, the second electrode 7, and the third electrodes 3 is a metal having high thermal conductivity and electrical conductivity such as silver, and the thicknesses of the first electrode 4, the second electrode 7, and the third electrodes 3 can be increased to optimize the transmission of the heat flux and the current transfer and improve the output power of the thermoelectric module.

The third electrodes 3 are formed, for example, in a plate shape, the third electrodes 3 have the same length as the thermoelectric conversion elements 1, and the thermoelectric conversion elements 1 are higher and wider than the third electrodes 3; the two adjacent third electrodes 3 are misaligned in the height direction, and the tops of the third electrodes 31, 33, 35 are flush with one ends of the thermoelectric conversion elements 1 and connected to the first electrode 4; gaps 6 of 0.1 mm are reserved between the second electrode 7 and the bottoms of the third electrodes 31, 33, 35; gaps 6 of 0.1 mm are reserved between the first electrode 4 and the tops of the third electrodes 32, 34, and the bottoms of the third electrodes 32, 34 are flush with the other ends of the thermoelectric conversion elements 1 and connected to the second electrode 7.

Taking an n-type thermoelectric conversion module as an example, the operating principle of the thermoelectric conversion module proposed in the present embodiment is as follows:

The bottom surface of the thermoelectric module is a hot end, the top surface is a cold end, the bottom surface of the thermoelectric module is in contact with a heat source, the top surface of the thermoelectric module is in contact with air or a cooling device, then a temperature gradient field is established between the hot end and the cold end of the thermoelectric module.

When the top and bottom surfaces of the thermoelectric module have certain temperature difference, the heat flux flows in order of the second substrate 8, the second electrode 7, the third electrodes 32, 34, the n-type thermoelectric conversion elements 1, the third electrodes 31, 33, 35, the first electrode 4, and the first substrate 2.

Since the thermal conductivity of the third electrodes 3 is extremely high, which is about several hundred times the thermal conductivity of the thermoelectric material, when in a steady state, the temperature of the third electrodes 32, 34 is higher than the temperature of the n-type thermoelectric conversion elements 1 at the same horizontal position, and the temperature of the third electrodes 31, 33, 35 is lower than the temperature of the n-type thermoelectric conversion elements 1 at the same horizontal position, that is, a temperature difference is formed between the left and right sides of the individual flat n-type thermoelectric conversion element 1.

Due to the Seebeck effect, electrons inside the n-type thermoelectric conversion elements 1 at the high-temperature end begin to diffuse toward the low-temperature end under the driving of the temperature field, thereby forming a potential difference between the left and right sides of the n-type thermoelectric conversion elements 1. After the load resistor is connected, current transmitted opposite to the direction of the heat flux is generated in the circuit, and the plurality of n-type thermoelectric conversion elements 1 are connected in a thermoelectric transmission mode of thermal-parallel connection and electrical-parallel connection.

For a p-type thermoelectric conversion module, the transmission mode and direction of heat flux are the same as those of the n-type thermoelectric conversion module, but the flow direction of current is consistent with that of the heat flux.

The thermoelectric conversion module proposed in the present embodiment, which employs an electro-thermal conduction mode of electrical-parallel connection and thermal-parallel connection, has high output voltage and high operating current, thereby greatly improving the output power. Moreover, the module is made of only one kind of n-type or p-type thermoelectric material, and high output power can be achieved without considering the problem of performance matching of n-type and p-type thermoelectric materials.

### Embodiment 2

The present embodiment provides a thermoelectric conversion module capable of achieving high output power under certain temperature difference.

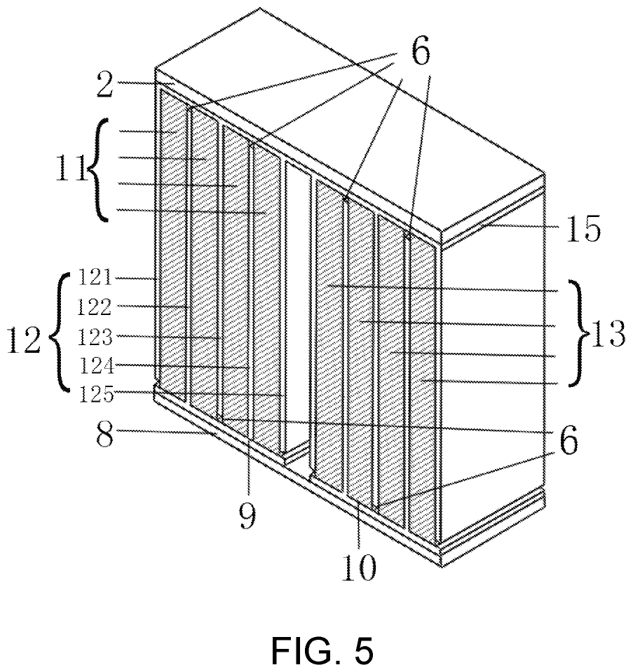

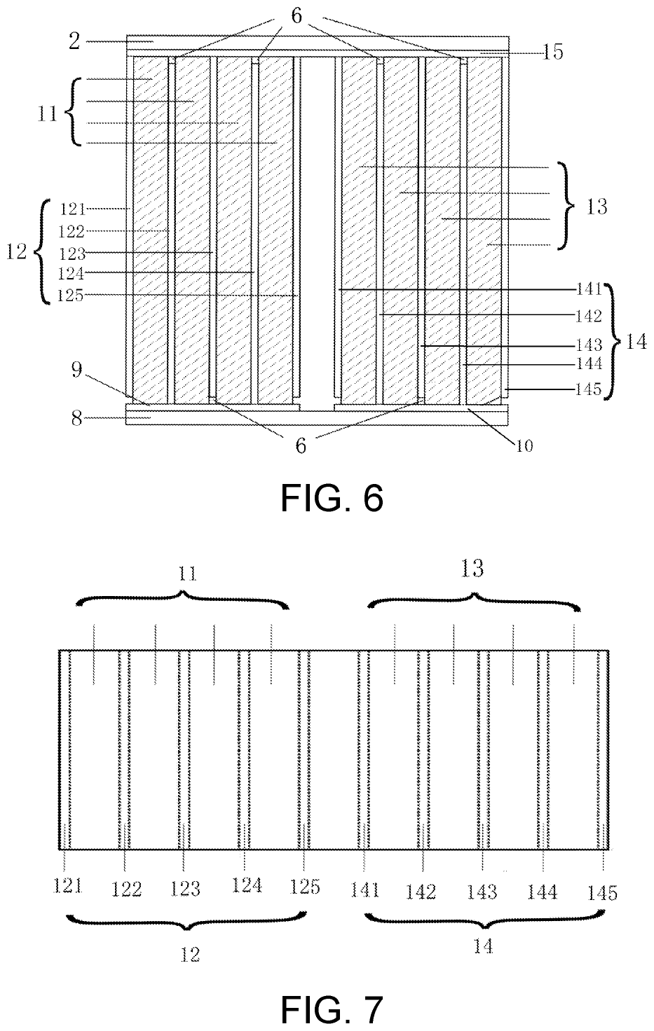

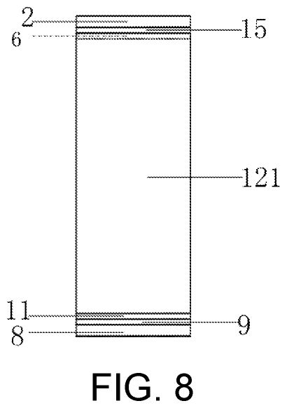

FIG. 5 is a perspective view of a thermoelectric conversion module according to Embodiment 2. FIG. 6 is a front view of FIG. 5, FIG. 7 is a top view of FIG. 5, and FIG. 8 is a side view of FIG. 5. The thermoelectric conversion module of the present embodiment includes a first substrate 2 made of ceramic, a first outer electrode 15, a plurality of n-type thermoelectric conversion elements 11, a plurality of first inner electrodes 12, a plurality of p-type thermoelectric conversion elements 13, a plurality of second inner electrodes 14, a second outer electrode 9, a third outer electrode 10, and a second substrate 8 made of ceramic.

Specifically, the first substrate 2 and the second substrate 8 are disposed opposite to each other, the plurality of first inner electrodes 12 and the n-type thermoelectric conversion elements 11 are arranged crosswise in a matrix along the width and disposed between the first substrate 2 and the second substrate 8, an n-type thermoelectric conversion element 11 is disposed between two adjacent first inner electrodes 12, one end of the n-type thermoelectric conversion element 11 is flush with the top of one first inner electrode 12 and the other end of the n-type thermoelectric conversion element 11 is flush with the bottom of the other first inner electrode 12; the plurality of second outer electrodes 14 and the p-type thermoelectric conversion elements 13 are arranged crosswise in a matrix along the width and disposed between the first substrate 2 and the second substrate 8, a p-type thermoelectric conversion element 13 is disposed between two adjacent second inner electrodes 14, one end of the p-type thermoelectric conversion element 13 is flush with the top of one second inner electrode 14 and the other end of the p-type thermoelectric conversion element 13 is flush with the bottom of the other second inner electrode 14; the first outer electrode 15 is disposed on the inner side surface of the first substrate 2, and electrically connected in parallel to one ends of the plurality of n-type thermoelectric conversion elements 11, the first inner electrodes 121, 123, 125 whose tops are flush with the one ends of the n-type thermoelectric conversion elements 11, one ends of the plurality of p-type thermoelectric conversion elements 13, and the second inner electrodes 141, 143, 145 whose tops are flush with the one ends of the p-type thermoelectric conversion elements 13, respectively; the second outer electrode 9 and the third outer electrode 10 are disposed on the inner side surface of the second substrate 8, and the second outer electrode 9 is electrically connected in parallel to the other ends of the plurality of n-type thermoelectric conversion elements 11, and the first inner electrodes 122, 124 whose bottoms are flush with the other ends of the n-type thermoelectric conversion elements 11, respectively; the third outer electrode 10 is electrically connected in parallel to the other ends of the plurality of p-type thermoelectric conversion elements 13, and the second inner electrodes 142, 144 whose bottoms are flush with the other ends of the p-type thermoelectric conversion elements 13, respectively.

According to the thermoelectric conversion module proposed in the present embodiment, the first inner electrodes, the n-type thermoelectric conversion elements and the like constitute n-type thermoelectric legs, and the second inner electrodes, the p-type thermoelectric conversion elements and the like constitute p-type thermoelectric legs. When the upper and lower ends of the module have certain temperature difference, if the upper end is a hot end, the heat flux in the individual n-type thermoelectric leg flows in order of the first substrate 2, the first outer electrode 15, the first inner electrodes 121, 123, 125, the n-type thermoelectric conversion elements 11, the first inner electrodes 122, 124, the second outer electrode 9, and the second substrate 8, and the heat flux in the individual p-type thermoelectric leg flows in order of the first substrate 2, the first outer electrode 15, the second inner electrodes 141, 143, 145, the p-type thermoelectric conversion element 13, the second inner electrodes 142, 144, the third outer electrode 10, and the second substrate 8;

If the lower end is a hot end, the heat flux in the individual n-type thermoelectric leg flows in order of the second substrate 8, the second outer electrode 9, the first inner electrodes 122, 124, the n-type thermoelectric conversion elements 11, the first inner electrodes 121, 123, 125, the first outer electrode 15, and the first substrate 2, and the heat flux in the individual p-type thermoelectric leg flows in order of the second substrate 8, the third outer electrode 10, the second inner electrodes 142, 144, the p-type thermoelectric conversion elements 13, the second inner electrodes 141, 143, 145, the first outer electrode 15, and the first substrate 2.

In the present embodiment, the n-type thermoelectric conversion elements 11 are formed, for example, in a plate shape, and the thermoelectric conversion elements 11 are made of an n-type thermoelectric material. Due to the Seebeck effect, carrier electrons in the n-type thermoelectric material move from the hot end to the cold end, and a potential difference is then generated at the two ends of the thermoelectric material. After a load resistor is applied, current is generated in the circuit composed of the thermoelectric module and the load resistor, the current in the n-type thermoelectric material is conducted opposite to the direction of the heat flux, and the plurality of n-type thermoelectric conversion elements 11 are connected in electrical-parallel connection and thermal-parallel connection.

The p-type thermoelectric conversion elements 13 are formed, for example, in a plate shape, and the thermoelectric conversion elements 13 are made of a p-type thermoelectric material. Due to the Seebeck effect, carrier holes in the p-type thermoelectric material move from the hot end to the cold end, and a potential difference is then generated at the two ends of the thermoelectric material. After a load resistor is applied, current is generated in the circuit composed of the thermoelectric module and the load resistor, the current in the p-type thermoelectric material is conducted along the direction of the heat flux, and the plurality of p-type thermoelectric conversion elements 13 are connected in electrical-parallel connection and thermal-parallel connection.

The size of the n-type thermoelectric conversion elements 11 and the p-type thermoelectric conversion elements 13 is 0.5×2×5 mm³, and the size is not fixed.

In the present embodiment, the first substrate 2 is formed, for example, in a plate shape, is electrically insulated, has good thermal conductivity, and covers the one ends of the plurality of thermoelectric conversion elements. The second substrate 8 is formed, for example, in a plate shape, is electrically insulated, has good thermal conductivity, and covers the other ends of the plurality of thermoelectric conversion elements. The size of the first substrate and the second substrate is 5.5×2×0.2 mm³, and the size is not fixed.

In the present embodiment, the material of the first outer electrode 15, the second outer electrode 9, and the third outer electrode 10 is a metal having high thermal conductivity and electrical conductivity such as silver; the size of the first outer electrode 15 is 5.5×2×0.1 mm³, the size of the second outer electrode 9 and the third outer electrode 10 is 2.5×2×0.1 mm³, and the sizes are not fixed. The increasing in the thicknesses of the first outer electrode 15, the second outer electrode 9 and the third outer electrode 10 facilitates the transmission of heat flux and current, and improves the output power of the thermoelectric module.

The material of the first inner electrodes 12 and the second inner electrodes 14 is a metal having high thermal conductivity and electrical conductivity such as silver, and the thicknesses of the first inner electrodes 12 and the second inner electrodes 14 can be increased to optimize the transmission of heat flux and current and improve the output power of the thermoelectric module.

The first inner electrodes 12 are formed, for example, in a plate shape, the first inner electrodes 12 have the same length as the n-type thermoelectric conversion elements 11, and the n-type thermoelectric conversion elements 11 are higher and wider than the first inner electrodes 12; the two adjacent first inner electrodes 12 are misaligned in the height direction, the tops of the first inner electrodes 121, 123, 125 are flush with one ends of the n-type thermoelectric conversion elements 11 and connected to the first outer electrode 15, gaps 6 of 0.1 mm are reserved between the second outer electrode 9 and the bottoms of the first inner electrodes 121, 123, 125, the bottoms of the first inner electrodes 122, 124 are flush with the other ends of the n-type thermoelectric conversion elements 11 and connected to the second outer electrode 9, and gaps 6 of 0.1 mm are reserved between the first outer electrode 15 and the tops of the first inner electrodes 122, 124.

The second inner electrodes 14 are formed, for example, in a plate shape, the second inner electrodes 14 have the same length as the p-type thermoelectric conversion elements 13, and the p-type thermoelectric conversion elements 13 are higher and wider than the second inner electrodes 14; the two adjacent second inner electrodes 14 are misaligned in the height direction, the tops of the second inner electrodes 141, 143, 145 are flush with one ends of the p-type thermoelectric conversion elements 13 and connected to the first outer electrode 15, gaps 6 of 0.1 mm are reserved between the third outer electrode 10 and the bottoms of the second inner electrodes 141, 143, 145, the bottoms of the second inner electrodes 142, 144 are flush with the other ends of the p-type thermoelectric conversion elements 13 and connected to the third outer electrode 10, and gaps 6 of 0.1 mm are reserved between the first outer electrode 15 and the tops of the second inner electrodes 142, 144.

The operating principle of the thermoelectric conversion module proposed in the present embodiment is as follows:

The bottom surface of the thermoelectric module is a hot end, the top surface is a cold end, the bottom surface of the thermoelectric module is in contact with a heat source, the top surface is in contact with air or a cooling device, and a temperature gradient field is established between the hot end and the cold end of the thermoelectric module.

When the top and bottom surfaces of the thermoelectric module have certain temperature difference, the heat flux flows in order of the second substrate 8, the second outer electrode 9, the third outer electrode 10, the first inner electrodes 122, 124, the second inner electrodes 142, 144, the n-type thermoelectric conversion elements 11, the p-type thermoelectric conversion elements 13, the first inner electrodes 121, 123, 125, the second inner electrodes 141, 143, 145, the first outer electrode 15, and the first substrate 2.

The second outer electrode 9 and the third outer electrode 10 are respectively configured as a ground end and a terminal, and a load resistor is connected between the ground end and the terminal to form a circuit. Due to the Seebeck effect, the current inside the thermoelectric module flows from the p-type thermoelectric legs to the n-type thermoelectric legs, and the thermoelectric module has a thermoelectric conduction mode of parallel heat transmission and series-parallel electrical transmission.

The thermoelectric conversion module proposed in the present embodiment, which is formed by n-type thermoelectric legs and p-type thermoelectric legs in series and employs an electro-thermal conduction mode of series-parallel electrical transmission and parallel thermal transmission, has high output voltage and high operating current, thereby greatly improving the output power. Under the same condition, the maximum output power of the thermoelectric module can reach five times the output power of the conventional thermoelectric module.

As an example, Bi_{0.8}Sb_{1.5}Te₃ (Science, 2008; 320: 634-8) and Bi₂Te_{2.79}Se_{0.21} (Adv. Energy Mater. 2015; 5: 1500411) are used as thermoelectric materials of the p-type thermoelectric conversion elements and the n-type thermoelectric conversion elements, Ag is the material of the first outer electrode, the second outer electrode, the third outer electrode, the first inner electrodes and the second inner electrodes, Al₂O₃ is the material of the first substrate and the second substrate. The comparison between the thermoelectric conversion module proposed in the present embodiment and the conventional thermoelectric conversion module further proves the superiority of the thermoelectric conversion module of the present embodiment.

The thermoelectric conversion elements of the conventional thermoelectric conversion module are usually cuboid or cylindrical, and have a thermoelectric transmission mode of thermal-parallel connection and electrical-series connection. The thermoelectric conversion elements of the thermoelectric conversion module of the present embodiment are formed by laminating a plate-shaped thermoelectric material provided with metal inner electrodes, and have a thermoelectric transmission mode of thermal-parallel connection and electrical-parallel connection. Through the thermoelectric transmission mode of thermal-parallel connection and electrical-parallel connection, the thermoelectric conversion module obtains low internal resistance and high operating current.

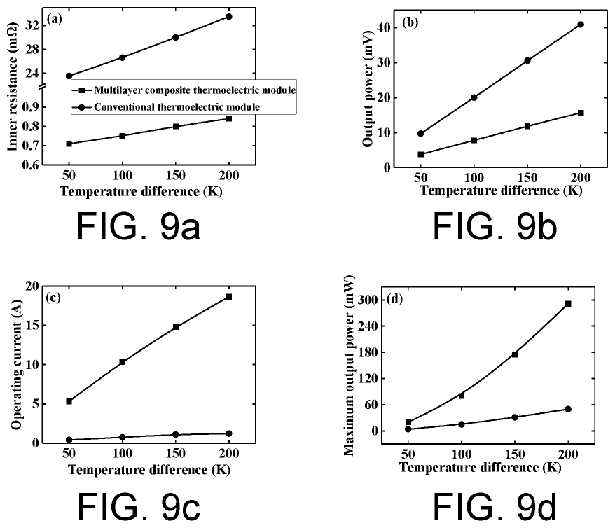

As shown in FIG. 9, the output voltage of the thermoelectric conversion module of the present embodiment is 40% of the conventional thermoelectric conversion module of the same material and the same thermoelectric material volume, but the internal resistance is only 3% of the internal resistance of the conventional thermoelectric conversion module. The slightly lower output voltage and the minimal internal resistance result in high operating current of the thermoelectric conversion module of the present embodiment in an operating state. Finally, under certain temperature difference, the thermoelectric conversion module of the present embodiment can obtain higher maximum output power, about five times that of the conventional thermoelectric module.

Based on the above, compared with the conventional thermoelectric power generation module, the thermoelectric conversion module of the present embodiment has a unique thermoelectric transmission mode of thermal-parallel connection and electrical-parallel connection, has low internal resistance and high operating current, and can achieve higher output power under the same condition.

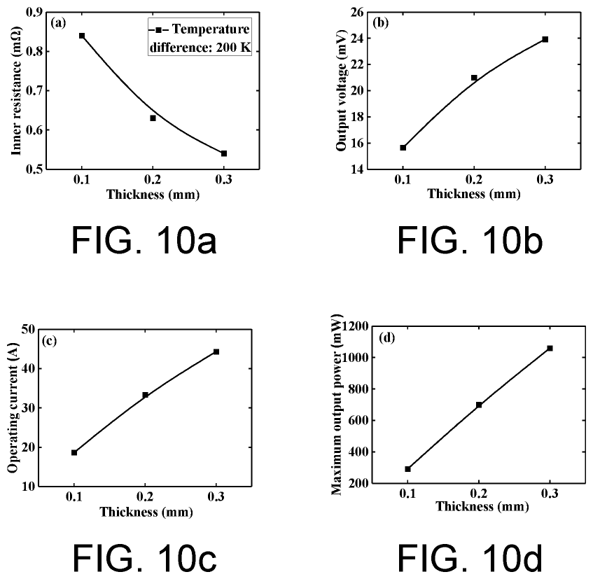

As shown in FIG. 10, as the thicknesses of the metal electrodes increase, the internal resistance of the thermoelectric conversion module of the present embodiment decreases, the output voltage and the operating current increase simultaneously, and then the maximum output power greatly increases. This is because the thick electrodes are favorable for the transmission of heat flux and current. The electrodes are thicker, the temperature difference between the two sides of the thermoelectric material is larger, which leads to the above result. Second, for the n-type and p-type thermoelectric materials having different electrical conductivity and thermal conductivity, the performance of the thermoelectric conversion module of the present embodiment can also be improved by optimizing the size ratio.

### Embodiment 3

The present embodiment provides a thermoelectric conversion system, including the thermoelectric conversion module of Embodiment 2 and a heat source disposed on the second substrate. According to the above system, the above effects can be achieved. In addition, the thermoelectric conversion module of Embodiment 1 may also be applied to the present system.

Compared with the conventional thermoelectric power generation module, the thermoelectric conversion module and the thermoelectric conversion system proposed in the present embodiment have a unique thermoelectric transmission mode of thermal-parallel connection and electrical-parallel connection, have low internal resistance and high operating current, and can achieve higher output power under the same condition.

### Industrial Practicality

The thermoelectric conversion module and system of the present disclosure can realize the recycling of low-quality heat sources such as industrial waste heat, geothermal heat and automobile tail heat, and are more advantageous in an operating environment with low heat source temperature and sufficient heat flux. In addition, continuous power can be provided for spacecrafts in deep space exploration.

Described above are merely preferred embodiments of the present application, and the present application is not limited thereto. Various modifications and variations may be made to the present application for those skilled in the art. Any modification, equivalent substitution, improvement or the like made within the spirit and principle of the present application shall fall into the protection scope of the present application.

Although the specific embodiments of the present invention are described above in combination with the accompanying drawings, the protection scope of the present invention is not limited thereto. It should be understood by those skilled in the art that various modifications or variations could be made by those skilled in the art based on the technical solution of the present invention without creative effort, and these modifications or variations shall fall into the protection scope of the present invention.

1. A thermoelectric conversion module, comprising:
a first substrate made of ceramic;
a second substrate made of ceramic and disposed opposite to the first substrate;
a plurality of third electrodes and a plurality of thermoelectric conversion elements arranged crosswise in a matrix between the first substrate and the second substrate;
a first electrode disposed between the first substrate and the thermoelectric conversion elements, and the first electrode is disposed between the first substrate and the third electrodes; and
a second electrode disposed between the second substrate and the thermoelectric conversion elements, and the second electrode is disposed between the second substrate and the third electrodes,
wherein the first electrode is connected to one ends of the thermoelectric conversion elements and the third electrodes whose tops are flush with the one ends of the thermoelectric conversion elements, respectively;
wherein the second electrode is connected to the other ends of the thermoelectric conversion elements and the third electrodes whose bottoms are flush with the other ends of the thermoelectric conversion elements, respectively.

2. The thermoelectric conversion module according to claim 1, wherein the third electrodes have the same length as the thermoelectric conversion elements, and the thermoelectric conversion elements are higher and wider than the third electrodes; and the thermoelectric conversion elements are made of only one kind of n-type or p-type thermoelectric conversion elements.

3. The thermoelectric conversion module according to claim 1, wherein two adjacent third electrodes are misaligned in a height direction, a top of one third electrode is flush with one ends of the thermoelectric conversion elements and connected to the first electrode, and a gap is reserved between the second electrode and a bottom of the one third electrode; a gap is reserved between the first electrode and a top of the other third electrode, and a bottom of the other third electrode is flush with the other ends of the thermoelectric conversion elements and connected to the second electrode.

4. The thermoelectric conversion module according to claim 1, wherein the first electrode, the second electrode, and the third electrodes are made of the same material.

5. A thermoelectric conversion module, comprising:
a first substrate made of ceramic;
a second substrate made of ceramic and disposed opposite to the first substrate;
a plurality of first inner electrodes and a plurality of n-type thermoelectric conversion elements arranged crosswise in a matrix between the first substrate and the second substrate;
a plurality of second inner electrodes and a plurality of p-type thermoelectric conversion elements arranged crosswise in a matrix between the first substrate and the second substrate;
a first outer electrode disposed between the first substrate and the n-type thermoelectric conversion elements, the first outer electrode is disposed between the first substrate and the p-type thermoelectric conversion elements, the first outer electrode is disposed between the first substrate and the first inner electrodes, and the first outer electrode is disposed between the first substrate and the second inner electrodes;
a second outer electrode disposed between the second substrate and the n-type thermoelectric conversion elements, and the second outer electrode is disposed between the second substrate and the first inner electrodes; and
a third outer electrode disposed between the second substrate and the p-type thermoelectric conversion elements, and the third outer electrode is disposed between the second substrate and the second inner electrodes.

6. The thermoelectric conversion module according to claim 5, wherein two adjacent first inner electrodes are misaligned in a height direction, a top of one first inner electrode is flush with one ends of the n-type thermoelectric conversion elements, and a gap is reserved between the second outer electrode and the bottom of the one first inner electrode; a gap is reserved between the first outer electrode and a top of the other first inner electrode, and a bottom of the other first inner electrode is flush with the other ends of the n-type thermoelectric conversion elements.

7. The thermoelectric conversion module according to claim 5, wherein two adjacent second inner electrodes are misaligned in a height direction, a top of one second inner electrode is flush with one ends of the p-type thermoelectric conversion elements, and a gap is reserved between the third outer electrode and a bottom of the one second inner electrode; a gap is reserved between the first outer electrode and a top of the other second inner electrode, and a bottom of the other second inner electrode is flush with the other ends of the p-type thermoelectric conversion elements.

8. The thermoelectric conversion module according to claim 5, wherein the first outer electrode is connected to one ends of the n-type thermoelectric conversion elements, the first inner electrodes whose tops are flush with the one ends of the n-type thermoelectric conversion elements, one ends of the p-type thermoelectric conversion elements, and the second inner electrodes whose tops are flush with the one ends of the p-type thermoelectric conversion elements, respectively;
the second outer electrode is connected to the other ends of the n-type thermoelectric conversion elements, and the first inner electrodes whose bottoms are flush with the other ends of the n-type thermoelectric conversion elements, respectively;
the third outer electrode is connected to the other ends of the p-type thermoelectric conversion elements, and the second inner electrodes whose bottoms are flush with the other ends of the p-type thermoelectric conversion elements, respectively.

9. The thermoelectric conversion module according to claim 5, wherein the first outer electrode, the second outer electrode and the third outer electrode are made of the same material; the first inner electrodes and the second inner electrodes are made of the same material.

10. A thermoelectric conversion system, comprising:
the thermoelectric conversion module according to claim 1; and
a heat source disposed on the second substrate.

11. A thermoelectric conversion system, comprising:
the thermoelectric conversion module according to claim 2; and
a heat source disposed on the second substrate.

12. A thermoelectric conversion system, comprising:
the thermoelectric conversion module according to claim 3; and
a heat source disposed on the second substrate.

13. A thermoelectric conversion system, comprising:
the thermoelectric conversion module according to claim 4; and
a heat source disposed on the second substrate.

14. A thermoelectric conversion system, comprising:
the thermoelectric conversion module according to claim 5; and
a heat source disposed on the second substrate.

15. A thermoelectric conversion system, comprising:
the thermoelectric conversion module according to claim 6; and
a heat source disposed on the second substrate.

16. A thermoelectric conversion system, comprising:
the thermoelectric conversion module according to claim 7; and
a heat source disposed on the second substrate.

17. A thermoelectric conversion system, comprising:
the thermoelectric conversion module according to claim 8; and
a heat source disposed on the second substrate.

18. A thermoelectric conversion system, comprising:
the thermoelectric conversion module according to claim 9; and
a heat source disposed on the second substrate.
